(19) United States
(12) Patent Application Publication
(10) Pub. No.: US 2025/0105383 A1
(43) Pub. Date: Mar. 27, 2025

(54) BATTERY MANAGEMENT SYSTEM AND METHOD OF OPERATION

(71) Applicant: KS2 CORP INC., Montréal (CA)

(72) Inventors: Anthony Scappaticci, Montréal (CA); Boris Topchii, Saint Petersburgh (RU)

(73) Assignee: KS2 CORP INC., Montréal, QC (CA)

(21) Appl. No.: 18/899,172

(22) Filed: Sep. 27, 2024

Related U.S. Application Data
(60) Provisional application No. 63/540,796, filed on Sep. 27, 2023.

(51) Int. Cl. H01M 10/48; G01R 31/3842; G01R 31/392

(52) U.S. Cl. CPC H01M 10/482; G01R 31/3842; G01R 31/392; H01M 10/486; H01M 2220/20

(57) ABSTRACT

A battery energy storage system, comprising one or more rechargeable battery packs, each including a plurality of battery cells; and a battery management system (BMS) including a first circuitry configured for battery pack protection management, and a second circuitry configured for capacity management and to perform an auxiliary service while performing the capacity management. The first circuitry monitors an operating parameter of at least one cell of the plurality of cells to detect an occurrence of the operating parameter being outside a predetermined safe operating range. The second circuitry monitors cell voltage balancing of a plurality of cells of the battery pack to detect an occurrence of a cell being in a state of unbalance, and further monitors proper operation of the first circuitry. In response to detection of a faulty operation of the first circuitry, the second circuitry is configured to control the battery pack protection management.

### CROSS-REFERENCE TO RELATED APPLICATION

The present application claims the benefit of U.S. provisional patent application Ser. No. 63/540,796 filed on Sep. 27, 2023. The contents of the above-referenced document are incorporated herein by reference in their entirety.

### TECHNICAL FIELD

The present disclosure relates to the field of rechargeable batteries, particularly to systems and methods for controlling charging and discharging of battery cells.

### BACKGROUND

Rechargeable batteries, such as lithium-based batteries, often benefit from a Battery Management System (BMS) to manage recharging operations and provide protection. The BMS is typically integrated into the battery and is designed to disconnect the internal battery cells from the external battery terminals in case of over-charge, over-discharge, over-current, short-circuit, and over-temperature.

Improving BMS and methods of operating same is crucial for the development and optimization of various battery technologies, including those used in electric vehicles (EVs), renewable energy storage systems, and portable electronics. Accordingly, there remains a need for an improved BMS and methods of operating same for controlling charging and discharging of battery cells.

### SUMMARY

This Summary is provided to introduce a selection of concepts in a simplified form that are further described below in the Detailed Description. This Summary is not intended to identify key aspects or essential aspects of the claimed subject matter.

Broadly stated, in some embodiments, the present disclosure relates to a battery energy storage system, comprising: one or more rechargeable battery packs, each including a plurality of battery cells; and a battery management system (BMS) including a first circuitry configured for battery pack protection management and a second circuitry configured for capacity management, wherein the second circuitry is further configured to perform an auxiliary service while performing the capacity management.

For example, the first circuitry monitors an operating parameter of at least one cell of the plurality of cells to detect an occurrence of the operating parameter being outside a predetermined safe operating range and in response to detection of the operating parameter being outside the predetermined safe operating range, interrupts the battery pack.

For example, the second circuitry monitors cell voltage balancing of a plurality of cells of a relevant battery pack to detect an occurrence of a cell being in a state of unbalance, and in response to detection of the cell being in the state of unbalance, controls a cell-to-cell active balancing of the plurality of cells by transferring current from a highest-voltage cell to a lowest voltage cell.

For example, the auxiliary service includes monitoring proper operation of the first circuitry and in response to detection of a faulty operation of the first circuitry, the second circuitry is configured to control the battery pack protection management.

In some embodiments, the battery storage system includes one or more of the following features:
the second circuitry manages communications with an external system, wherein the external system includes a computing device configured for implementing a user interface.
the computing device communicates with the BMS to perform one or more of: obtain and process diagnostic data, control or manage the protection management and capacity management functionalities, and control or manage charging or discharging activity of the one or more rechargeable battery packs.
the battery pack and the BMS are present within the same enclosure.
the battery pack and the BMS are connected to each other when there is an external device connected to the battery storage system.
the operating parameter may include one or more of cell voltage, battery pack voltage, cell temperature, battery pack current, or a state of balance of the plurality of cells.
the first circuitry monitors at least a voltage of a cell of the plurality of cells, and in response to detection of the voltage of the cell exceeding a voltage limit, the first circuitry is configured to interrupt the battery pack to prevent damage to the battery pack.
the system further comprising a contactor electrically connecting the battery pack to a positive terminal of the battery storage system, wherein the first circuitry interrupts the battery pack by controlling the contactor to disconnect the battery pack from the positive terminal.
further comprising a voltage sensor, probe or transducer connected to the plurality of cells, wherein the voltage sensor, probe or transducer is configured for measuring the voltage of the cell of the plurality of cells and transmitting the cell voltage measurement to the first circuitry.
the second circuitry is in communication with the first circuitry via a communication interface, and is configured for communicating the safe operating parameter range to the first circuitry.
in response to detection of a state of balance of the plurality of cells indicative that a cell is in a state of unbalance, the second circuitry is configured to control an active balancer for performing the cell-to-cell active balancing of the plurality of cells.
the auxiliary service includes one or more of: communicating one or more operating parameter limits to the first circuitry, monitoring measurement results of the first circuitry, managing a failure mode in case battery pack protection management fails, save battery storage system status to a computer readable storage device, manage system power modes, control a recovery circuit to charge a deeply discharged cell that has been discharged below a lower voltage limit, and control an active heater for heating the battery pack.
the capacity management is performed when the battery storage system is in charging, discharging, idle and sleep mode.
the second circuitry manages communications with an external system, wherein the external system includes a computing device configured for implementing a user interface.
the user interface is capable of communicating with the BMS to obtain and process diagnostic data, control or manage the protection management and capacity management functionalities, and control or manage the one or more rechargeable battery packs
the active balancer includes a plurality of relays for cell switching.
the active balancer further includes an output rectifier circuit having a plurality of Schottky diodes.
the output rectifier circuit includes an inductor to minimize inherent parametric resonance of the Schottky diodes.
the output rectifier circuit includes a thermistor to control a board temperature of an area of a board to which the Schottky diodes are mounted to prevent overheating of the Schottky diodes.
the battery pack is a lithium-ion battery pack.
the system is associated with an electric vehicle, a renewable energy storage system, or a portable electronic.

Broadly stated, in some embodiments, the present disclosure relates to a method for a battery energy storage system, the battery energy storage system including one or more rechargeable battery packs, each including a plurality of battery cells; and a battery management system (BMS) including a first circuitry configured for battery pack protection management and a second circuitry configured for capacity management, wherein the second circuitry is further configured to perform an auxiliary service while performing the capacity management, the method comprising: with the first circuitry, monitoring an operating parameter of at least one cell of the plurality of cells to detect an occurrence of the operating parameter being outside a predetermined safe operating range, and in response to detection of the operating parameter being outside the predetermined safe operating range, interrupting the battery pack; with the second circuitry, monitoring cell voltage balancing of a plurality of cells of a battery pack to detect an occurrence of a cell being in a state of unbalance, and in response to detection of the cell being in the state of unbalance, controlling a cell-to-cell active balancing of the plurality of cells by transferring current from a highest-voltage cell to a lowest voltage cell; and with the second circuitry, monitoring proper operation of the first circuitry and in response to detection of a faulty operation of the first circuitry, control the battery pack protection management.

In some embodiments, the method includes one or more of the following features:
the operating parameter may include one or more of cell voltage, battery pack voltage, cell temperature, battery pack current, or a state of balance of the plurality of cells.
the first circuitry monitors at least a voltage of a cell of the plurality of cells, and in response to detection of the voltage of the cell exceeding a voltage limit, the first circuitry is configured to interrupt the battery pack to prevent damage to the battery pack.
the battery storage system further comprises a contactor electrically connecting the battery pack to a positive terminal of the battery storage system, wherein the first circuitry interrupts the battery pack by controlling the contactor to disconnect the battery pack from the positive terminal.
the battery storage system further comprises a voltage sensor, probe or transducer connected to the plurality of cells, and which is configured for measuring the voltage of the cell of the plurality of cells and transmitting the cell voltage measurement to the first circuitry.
the capacity management is performed when the battery storage system is in charging, discharging, idle and sleep mode.
the second circuitry further communicates one or more operating parameter limits to the first circuitry, monitors measurement results of the first circuitry, manages a failure mode in case battery pack protection management fails, saves battery storage system status to a computer readable storage device, manages system power modes, controls a recovery circuit to charge a deeply discharged cell that has been discharged below a lower voltage limit, or controls an active heater for heating the battery pack.

All features of exemplary embodiments which are described in this disclosure and are not mutually exclusive can be combined with one another. Elements of one embodiment can be utilized in the other embodiments without further mention. Other aspects and features of the present disclosure will become apparent to those ordinarily skilled in the art upon review of the following description of specific embodiments in conjunction with the accompanying Figures.

### BRIEF DESCRIPTION OF THE DRAWINGS

A detailed description of specific exemplary embodiments is provided herein below with reference to the accompanying drawings in which:

FIG. 1 shows a non-limiting functional block diagram of a battery storage system including a battery pack and a battery management system (BMS), electrically connected to an external device, in accordance with an embodiment of the present disclosure.

FIG. 2 shows a non-limiting functional block diagram of a battery management system (BMS), in accordance with an embodiment of the present disclosure.

FIG. 3 shows a non-limiting illustration of an active balancer circuitry, in accordance with an embodiment of the present disclosure.

FIG. 4 shows a non-limiting illustration of a variant of the active balancer circuitry of FIG. 3, in accordance with an embodiment of the present disclosure.

FIG. 5 shows a non-limiting functional block diagram representing interactions between a BMS and a computing device, in accordance with an embodiment of the present disclosure.

FIG. 6 shows a non-limiting functional block diagram representing interactions between a BMS and first and second computing devices, in accordance with an embodiment of the present disclosure.

FIG. 7 shows a non-limiting flowchart illustrating method steps for obtaining battery status data from a BMS according to an embodiment of the present disclosure.

FIG. 8 shows a non-limiting flowchart illustrating method steps for presenting battery diagnostic data via a user interface according to an embodiment of the present disclosure.

FIG. 9 shows a non-limiting representation of a graphical user interface presenting battery diagnostic data or battery status data according to an embodiment of the present disclosure.

In the drawings, exemplary embodiments are illustrated by way of example. It is to be expressly understood that the description and drawings are only for the purpose of illustrating certain embodiments and are an aid for understanding. They are not intended to be a definition of the limits of the disclosure.

### DETAILED DESCRIPTION

The present technology is explained in greater detail below. This description is not intended to be a detailed catalog of all the different ways in which the technology may be implemented or all the features that may be added to the instant technology. For example, features illustrated with respect to one embodiment may be incorporated into other embodiments, and features illustrated with respect to a particular embodiment may be deleted from that embodiment. In addition, numerous variations and additions to the various embodiments suggested herein will be apparent to those skilled in the art considering the instant disclosure which variations and additions do not depart from the present technology. Hence, the following description is intended to illustrate some embodiments of the technology, and not to exhaustively specify all permutations, combinations, and variations thereof.

The present inventors have surprisingly and unexpectedly identified a technical shortcoming with known rechargeable battery storage systems and battery management system (BMS) associated therewith and propose herein a technical solution, which affords one or more advantages.

The present disclosure relates to a battery energy storage system. Such battery energy storage system can be configured to store electrical energy and discharge the stored electrical energy to an external system. The battery energy storage system includes one or more rechargeable battery pack, each pack including a plurality of cells, and a battery management system (BMS).

The BMS is capable of performing one or more of the following functionalities: controlling and managing the one or more rechargeable battery pack, communicating with an energy management system, communicating with various loads or charges associated with the battery energy storage system, performing battery pack protection management and capacity management functionalities, and any combinations thereof.

Advantageously, the BMS includes a first circuitry configured to perform the battery pack protection management and a second circuitry configured to perform the capacity management. In some embodiments, the second circuitry is further configured to perform auxiliary services while performing the capacity management.

In some embodiments, the auxiliary services performed by the second circuitry include one or more of the following: communicating one or more operating parameter limits to the first circuitry, monitoring measurement results from the first circuitry, managing a failure mode in the event that the battery pack protection management performed by the first circuitry fails, saving the battery storage system status to a computer-readable storage device, communicating with external computing devices such as a device implementing an energy management system (EMS), managing system power modes, controlling a recovery circuit to charge a deeply discharged cell that has been discharged below a lower voltage limit, controlling an active heater for heating the battery pack, and monitoring the proper operation of the first circuitry.

For example, in response to detecting a faulty operation of the first circuitry, the second circuitry may be configured to take over the control of battery pack protection management. This configuration provides enhanced system reliability and fault tolerance, as the second circuitry is able to maintain battery protection in the event of a failure in the first circuitry. Additionally, the ability to perform auxiliary services concurrently with capacity management allows for efficient system operation and real-time response to changes in battery conditions.

In some embodiments, the second circuitry may also manage communications with one or more external systems to ensure coordinated system-level management and data logging, thereby improving overall operational efficiency and extending the lifespan of the battery storage system. For example, the one or more external systems may include a computing device configured for implementing a user interface. For example, the computing device may allow implementing an energy management system, or may allow managing or controlling a plurality of charges, a plurality of loads, or a combination thereof.

In some instances, the battery energy storage system may include one or more rechargeable battery packs. For example, the one or more rechargeable battery packs can be used for supplying/storing energy in relation to various loads and charges. For example, the various loads and charges may include electric vehicles, solar panels, powder grids, household or industrial building loads (e.g., hot water tank, HVAC systems, etc.), and the like.

For example, the battery energy storage system may be utilized to support the electric power grid with the assistance of an energy conversion system, such as a charger/inverter. For example, the charger/inverter operates either as a charger or as an inverter depending on the direction of energy flow. The charger/inverter operates as a charger by receiving AC power flow from the electric power grid and converting the incoming electrical energy from AC to DC. When the charger/inverter operates as a charger, the output may therefore be a rectified electrical energy flow, which for convenience is referred to herein as DC, although in some cases the flow may not necessarily be a pure DC one as some ripples are likely to be present. The charger/inverter also operates as an inverter by receiving DC power flow generated by the battery and converting it into AC form for injection in the grid. The electric power grid may comprise a plurality of loads, such as those found in residential households, commercial establishments, and industrial facilities. During normal operation, the electric power grid operates in a steady state, wherein there is equilibrium between the generation side, which includes power generation sources such as power plants, and the load side, which includes households, industrial buildings, and other energy-consuming entities. In the event of a disturbance that disrupts this equilibrium—such as an imbalance between the power generation side and the load side, particularly in the case of a generation deficit due to an accidental loss of a power generator—the battery energy storage system may be deployed to stabilize the grid. The battery energy storage system can be configured to mitigate or eliminate the imbalance for a duration that is determined by the system and the magnitude of the imbalance between power generation and load demand. In an additional embodiment, the battery energy storage system can be configured to support the electric power grid in the event of a reverse imbalance, wherein the power generation exceeds the load demand. In this scenario, the battery energy storage system is capable of absorbing at least a portion of the excess energy generated by the grid, thus maintaining grid stability. This embodiment of the battery energy storage system enables flexible and efficient grid support during both power generation deficits and surpluses, enhancing the reliability of the electric power grid.

In some instances, the battery energy storage system may include a user interface through which a user can interact with and manage the battery energy storage system. Such user interface is capable of communicating with the BMS to obtain and process diagnostic data, control or manage the protection management and capacity management functionalities, and control or manage the one or more rechargeable battery packs.

In some embodiments, the protection management may include monitoring an operating parameter of at least one cell of the plurality of cells of a battery pack to detect an occurrence of the operating parameter being outside a predetermined safe operating range, and in response to detection of the operating parameter being outside the predetermined safe operating range, interrupting the battery pack.

In some embodiments, the operating parameter may include one or more of cell voltage, battery pack voltage, cell temperature, battery pack current, or a state of balance of the plurality of cells. Preferably, the operating parameter is one of voltage and state of balance of cells.

In some embodiments, the capacity management may include monitoring cell voltage balancing of a plurality of cells of a battery pack to detect an occurrence of one or more cells having a voltage value outside a predetermined voltage variation range relative to remaining cells of the plurality of cells, and in response to detection of the one or more cells having a voltage value outside the predetermined voltage variation range, controlling a cell-to-cell active balancing of the plurality of cells by transferring current from a highest-voltage cell to a lowest voltage cell. Such cell-to-cell active balancing includes transferring current from a highest-voltage cell to a lowest voltage cell without dissipating cell excessive power to heat or to the ground and without drawing current from the whole battery pack, ensuring that all cells maintain a consistent voltage and capacity.

In some embodiments, the capacity management operates when the battery storage system is in charging, discharging, idle and sleep mode.

Advantageously, the BMS is thus designed to prevent the cells from exceeding limits and protects them as well as the output (i.e., receiving device) so that no “over load” leaves the battery, and the BMS can be controlled via a user interface, thus allowing the user to define the limits using the user interface.

Advantageously, the BMS can be designed to detect and diagnose the entire life cycle of the battery energy storage system without requiring disassembly. During the charge and discharge cycles of the battery energy storage system, the BMS and the energy management system (EMS) can communicate bi-directionally via an industry-standard protocol, such as CAN or Modbus. During charging, the BMS utilizes real-time fault diagnosis methods to analyze operational data streams from the BMS to determine if there is a failure or potential safety hazard within the battery pack. This data stream is also transmitted to a cloud-based battery diagnostic platform via an intelligent communication gateway. The cloud diagnostic platform can analyze battery characteristics, including internal resistance and capacity, extracted from the data stream of individual cells. It assesses potential safety risks and identifies faulty cells by comparing the consistency of these characteristics with historical data. If the current operational values or the consistency of the battery characteristics exceed predefined safety and reliability thresholds, an alarm is triggered. The BMS or cloud platform then can automatically initiate a service request to maintenance personnel via the EMS, directing them to perform offline inspection and maintenance in accordance with pre-established inspection rules and intelligent maintenance protocols.

In some embodiments, the BMS is configured to store various parameters associated with the battery pack. For example, a maximum transient discharging current, a continuous charging/discharging current, a charging/discharging voltage threshold of each cell, and a charging/discharging voltage threshold of the battery module. The initial values and present control values of these parameters can be constrained by one or more of the following conditions: the present current threshold is less than or equal to the initial current threshold, the present charging voltage threshold is less than or equal to the initial charging voltage threshold, and the present discharging voltage threshold is greater than or equal to the initial discharging voltage threshold.

The BMS can further configured to regularly acquire updated control parameters from an intelligent gateway and apply these updates accordingly. Based on the maximum power and/or total energy requirements of the battery energy storage system during charging or discharging, and the present state of charge (SOC) of each cell, the BMS determines the charging or discharging current, time interval, and voltage threshold for each of the one or more battery packs. The BMS can also be configured to perform voltage balancing when the voltage consistency of the battery exceeds a preset threshold, according to predefined rules.

In some embodiments, the BMS is configured to store fault codes, fault information, and charging/discharging control parameters. The fault information is categorized into serious fault information and general fault information. Serious fault information includes, but is not limited to, indications of a micro-short circuit, thermal runaway, insulation abnormalities, overheating, and communication errors, as well as cases where the characteristic value or consistency parameter of the battery equals or exceeds a safety threshold. General fault information includes conditions such as cell undervoltage (CUV), cell overvoltage (COV), overcurrent in charge (OCC), overcurrent in discharge (OCD), short circuit in discharge (SCD), undertemperature in charge (UTC), undertemperature in discharge (UTD), overtemperature in charge (OTC), overtemperature in discharge (OTD), low state of charge (SOC), high SOC, balance faults, and cases where the characteristic value or consistency parameter of the battery (or a cell thereof) exceeds a reliability threshold but remains below the safety threshold.

### Practical Implementation

Specific implementations of the technical solution of the present disclosure are discussed in more details hereinafter.

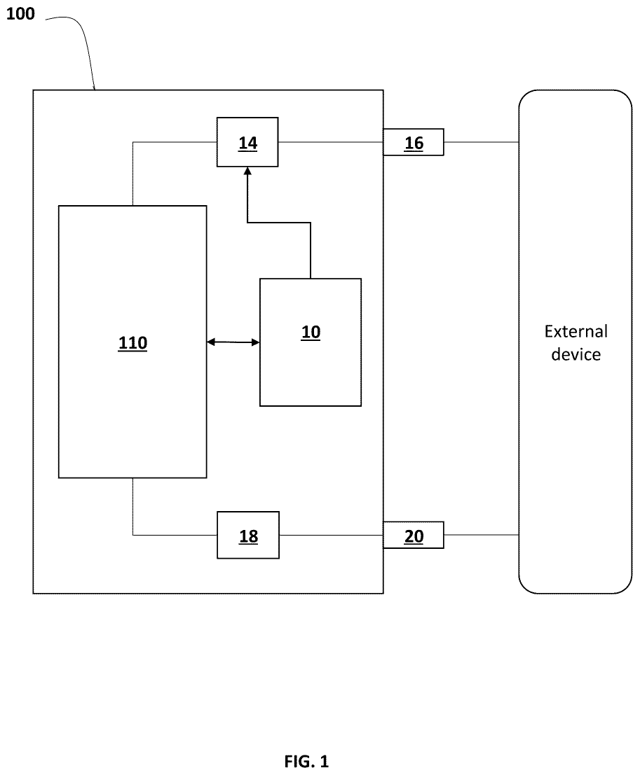

FIG. 1 illustrates a rechargeable battery energy storage system in accordance with an embodiment of the present disclosure. The rechargeable battery storage system is denoted generally by reference numeral 100. The rechargeable battery storage system 100 includes a rechargeable battery pack 110 and a battery management system (BMS) 10. While FIG. 1 illustrates the battery storage system 100 as being contained within one enclosure, it will be understood that the battery storage system 100 may include physically separated devices, where a first device includes the battery pack which is connectable to the second device which includes the BMS 10. It will also be understood that the battery pack and the BMS 10 are connected to each other when there is an external device connected to the battery storage system, such as a charger or a load. It will also be understood that while FIG. 1 illustrates one battery pack connected to the BMS 10, some embodiments may include more than one battery pack connected to the BMS 10.

The BMS 10 is capable of real-time monitoring of the one or more battery rechargeable battery pack 110 conditions. The BMS 10 enhances the operational efficiency of the one or more battery rechargeable battery pack 110, and can provide functions such as one or more of preventing overcharging and overdischarging, electrical leakage detection, thermal management, battery balancing, alarm notifications, residual capacity calculation, power discharge reporting, degradation state assessment, and the like.

As shown in FIG. 1, the battery pack 110 can be electrically connected to an external device, which can be a load or a source. In a charging mode, the battery pack 110 is supplied with power supplied from the external device, such as a generator or the power grid. In a discharging mode, the battery pack 110 can supply power to the external device, such as household devices or an electric vehicle.

The battery pack 110 may be a rechargeable an electrical battery of any chemistry such as, but not limited to, a lithium-based rechargeable battery. For example, a lithium-ion (Li-ion), lithium-polymer (LiPo) battery, or any equivalent rechargeable battery. For instance, the Li-ion battery may be a battery based on lithium cobalt oxide (LCO), lithium manganese oxide (LMO), lithium nickel manganese cobalt oxide (NMC), lithium iron phosphate (LFP), lithium nickel cobalt aluminum oxide (NCA), lithium titanate (LTO), or any equivalent li-ion battery. For example, the battery pack 110 may have any suitable size or operating performance. For instance, the battery pack 110 may provide up to about 800 Amp-Hour (AH) or any other AH value, such as from about 100 AH to about 800 AH including any value therein. For instance, the battery pack 110 may provide 12V, 24V, or 48V, or any other suitable voltage.

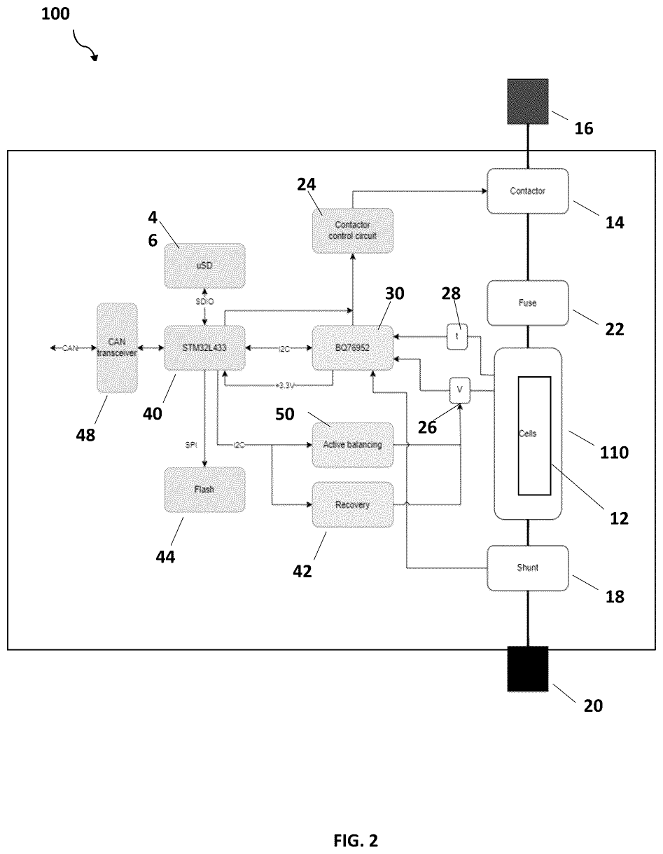

In the embodiment depicted by way of example in FIG. 1 and FIG. 2, the battery storage system 100 includes a contactor 14 (e.g., metal-oxide-semiconductor field-effect transistor (MOSFET), relay, or any suitable switching device) for electrically connecting the battery pack 110 to a positive terminal 16. The battery storage system 100 may also include a shunt 18 for electrically connecting the battery pack 110 to a negative terminal 20. Optionally, a fuse 22 may be disposed between the contactor 14 and the battery pack 110, as shown in FIG. 2. The battery pack 110 includes a plurality of individual cells 12, which can be connected in series and/or in parallel. The number of battery cells 12 included in a battery pack, in series and/or in parallel, may be changed according to a specific design.

In the embodiment depicted in FIG. 2, the battery management system (BMS) 10 includes elements for performing the battery pack protection management and capacity management.

The battery management system (BMS) 10 includes a first circuitry, shown in FIG. 2 as battery monitor and protector 30, for monitoring an operating parameter of at least one cell of the plurality of cells 12.

For example, the operating parameter may include one or more of individual cell voltage, total battery voltage, cell temperature, battery current, and a state of balance of the plurality of cells 12. For example, the battery monitor and protector 30 can monitor a voltage value of individual cells of the plurality of cells 12. It will be apparent that by processing the measure of the cell voltage value of the individual cells 12, the total voltage of the battery pack 110 can be readily determined from the cell configuration. For example, but without limitations, the voltage value can be in the range of 0-5V for a cell, 0-15V for a battery, 0-20V for a pack.

The battery monitor and protector 30 provides a first line of protection for the battery storage system 100 by monitoring operating parameters of at least one cell of the plurality of cells 12 to ensure that these operating parameters remain within a predetermined safe operating range. In response to the battery monitor and protector 30 detecting that an operating parameter (e.g., voltage and/or temperature) exceeds the predetermined safe operating range, the battery monitor and protector 30 is configured to interrupt the battery pack 110 to prevent damage to the battery pack 110. For example, the battery monitor and protector 30 is configured to disconnect the battery pack 110 from the positive terminal 16, or in other embodiments from the negative terminal 20.

In the illustrated embodiment, the battery monitor and protector 30 controls the contactor 14 to disconnect the battery pack 110 from the positive terminal 16 if any one of the cell voltages of the plurality of cells 12 exceeds a predetermined voltage limit, for example.

In some embodiments, the battery management system (BMS) 10 may include a contactor control circuit 24. In such embodiments, the battery monitor and protector 30 may be configured to signal the contactor control circuit 24 to control the contactor 14 to disconnect the battery pack 110 from the positive terminal 16.

It will be apparent to the reader that while in the embodiment described above, the contactor 14 is connected to the positive terminal, in other embodiments, the contactor 14 may be connected to the negative terminal 20 instead (which could be in case where the contactor 14 is a MOSFET, for example).

Voltage sensors, probes or transducers 26 may be connected to the plurality of cells 12 as shown in FIG. 2 to measure cell voltage value(s) of the plurality of cells 12 and transmit the cell voltage measurement to the battery monitor and protector 30. The shunt 18 can monitor the current energy that flows out of the plurality of cells 12, for example by measuring the real-time voltage of the system and/or the current draw, and can transmit such measurements to the battery monitor and protector 30.

In the embodiment illustrated in FIG. 2, the battery monitor and protector 30 also monitors a cell temperature value of the plurality of cells 12 and controls the contactor 14 in response to detecting if any one of the cell temperatures of the cells 12 exceeds a predetermined temperature limit. Temperature sensors, probes or transducers 28 may be connected or placed in close proximity to the plurality of cells 12 as shown in FIG. 2 to measure the cell temperatures of the plurality of cells 12 and transmit the temperature value to the battery monitor and protector 30.

The battery monitor and protector 30 may be a battery monitor and protector chip. For example, the battery monitor and protector chip may be a high accuracy battery monitor and protector chip such as the BQ76952 chip by Texas Instruments or any functionally equivalent chip, ASIC, integrated circuit or circuitry.

The battery monitor and protector 30 may thus monitor and measure cell voltage, battery and pack voltage, cell temperature, and battery current.

The battery management system (BMS) 10 further includes a second circuitry, shown in FIG. 2 as master controller 40 (also known as a master control unit (MCU) or a host controller), for controlling the capacity management.

The master controller 40 is in communication with the battery monitor and protector 30 via a communication interface, e.g. via an I2C interface. Another functionally equivalent communication protocol may be used. The master controller 40 may perform various functions such as communicating voltage limits, temperature limits or other thresholds or operating ranges or parameters to the battery monitor and protector 30. These limits may be communicated in the form of a configuration file or in any other suitable format.

In some embodiments, the master controller 40 communicates with the battery monitor and protector 30 to set the predetermined safe operating parameter, such as voltage limit and/or temperature limit, for the battery monitor and protector 30.

In some embodiments, the master controller 40 may receive measurements from the battery monitor and protector 30, e.g. voltage and/or temperature readings from the voltage and/or temperature sensors 26, 28. For example, and as shown in FIG. 2, the master controller 40 may communicate with the battery monitor and protector 30 to receive a cell voltage value measured at the voltage sensor, probe or transducer 26. In response to detecting a lack of voltage balance between the plurality of cells 12, the master controller 40 is configured to enter into an active balancing mode. In an active balancing mode, the master controller 40 is configured to control an active balancer 50 to actively balance the plurality of cells 12 by drawing current from a highest-voltage cell to charge a lowest-voltage cell.

The master controller 40 may be a low power general purpose MCU such as the STM32L433 by STMicroelectronics or any functionally equivalent chip, ASIC, integrated circuit or circuitry. The master controller 40, battery monitor and protector 30 and other electronic components described herein may be mounted to a printed circuit board (PCB).

The master controller 40 is further configured to perform various auxiliary services at the same time as controlling the capacity management.

For example, the auxiliary services may include one or more of: communicating one or more operating parameter limits to the first circuitry, monitoring measurement results of the first circuitry, managing a failure mode in case battery pack protection management fails, save battery storage system status to a computer readable storage device, communicate with external computing devices, manage system power modes, control a recovery circuit to charge a deeply discharged cell that has been discharged below a lower voltage limit, control an active heater for heating the battery pack, and monitoring proper operation of the first circuitry. In response to detection of a faulty operation of the first circuitry, the master controller 40 is configured for controlling the battery pack protection management.

For example, the master controller 40 may be configured for monitoring proper operation of the battery monitor and protector 30, e.g., by communicating with the battery monitor and protector 30 to ensure the latter is operable, e.g. to verify that there is proper I2C communication and/or to ensure all operating values and parameters are within a prescribed operating range(s). For example, the master controller 40 may be configured for adjusting the control parameters for the contactor control circuit 24. The master controller 40 may be configured for managing a failure mode. The failure mode may be triggered or arise, for example, if the battery monitor and protector 30 does not act normally or as expected. For example, if the battery monitor and protector attempts to reset, or if the contactor control circuit 24 repeatedly fails to open the contactor 14, or if a contactor position feedback signal is not as expected, the master controller 40 can enter a failure mode to override one or more function of the battery monitor and protector 30 and/or to reconfigure or reset the battery monitor and protector 30. The master controller 40 may be configured to manage power modes, to control the active balancer 50 and to control active heaters as will be further described below. The master controller 40 thus acts as a second-level protector that monitors the battery monitor and protector 30 (first-level protector) and also, as described herein, implements various auxiliary functions.

In some embodiments, in response to detecting that a voltage cell value has reached a value below a lower voltage limit (a “deeply discharged cell”), the master controller 40 is configured to enter into a recovery mode. Recovery mode is the mechanism to gently restore cell charge in case it dropped below a low voltage limit. Recovery mode may require external power to be applied and regulates cell charge current, i.e., in this mode, external terminal power acts as power source for particular cell charging, or may use a battery pack-to-cell active balancing.

When entering recovery mode, the master controller 40 controls a recovery circuit 42 to charge a deeply discharged cell that has been discharged below a lower voltage limit. The lower voltage limit is the lowest operating voltage of the normal operating range and may be user-specified or predetermined by the BMS 10. For example, for a LifePO₄ battery, the lower voltage limit may be 2.5 V/cell. For example, for a LiPo battery with a nominal 3.7 V/cell, the normal operating range may be 3.2 V/cell-4.2 V/cell. The lower voltage limit could thus be set at 3.2 V/cell. Any cell which voltage drops below 3.2 V/cell would be considered a deeply discharged cell for which the recovery circuit 42 is used to recover the deeply discharged cell.

In some embodiments, the master controller 40 is configured to deactivate the recovery circuit 42 when the deeply discharged cell has reached the lower voltage limit and to then activate the active balancer 50.

In some embodiments, the BMS 10 may include a memory to store a log of battery data or system status data collected by one or both of the battery monitor and protector 30 and the master controller 40. Some examples of system status data include a timestamp, cell voltages, cell temperatures, battery voltage, SOC, external (power supply) voltage, current, battery monitor and protector status, e.g. operating mode, charge/discharge mode. For example, the memory is capable of storing the log of battery data or system status data each associated with a respective one of the one or more battery packs of the battery energy storage system.

In the non-limiting embodiment of FIG. 2, the memory may include a flash memory 44 and/or a micro SD card 46. Flash memory 44 may be used to store system status data for troubleshooting and customer service (e.g. charge/discharge state change, reset/reboot, power off). The micro-SD card 46 may be used to store data for debugging purposes, e.g. it may store data of MCU traces (i.e. trace events of the master controller such as breaking protection limits, parameter changes or other debugging information).

In some embodiments, the battery storage system 100 includes an active heater for actively heating the battery pack 110, such as an active heater pad. The active heater is controlled by the master controller 40 in response to receiving temperature data from the battery monitor and protector 30. There may be one active heater or multiple active heaters. The expression “active heater” signifies that this form of heating is distinct from the resistive heating that occurs inherently when current flows through the battery pack 110. The active heater is useful primarily when operating in cold weather, e.g. below freezing. An activation temperature for activating the active heater(s) may be user-specified or predetermined by the BMS 10. Optionally, the battery storage system 100 may also include a cooling device to cool the battery to prevent overheating, which would also be controlled by the master controller 40 in response to receiving temperature data from the battery monitor and protector 30.

Various types of active heaters may be implemented the battery storage system 100 to maintain or raise battery temperature, particularly in cold environments where performance and capacity degradation may occur.

In some embodiments, the active heater comprises a resistive heater. The resistive heater is configured to generate heat by passing electric current through a resistive element, such as a metal or carbon-based material, to increase the temperature of the battery cells. In further embodiments, the resistive heater is integrated into the battery pack to ensure uniform heating of the cells. In other embodiments, the active heater comprises a Positive Temperature Coefficient (PTC) heater. The PTC heater is configured such that the resistance of the heating element increases with rising temperature. This self-regulating behavior ensures that excessive heating is prevented. The PTC heater is further configured to limit current flow as the temperature increases, thereby maintaining safe operation of the battery pack. In yet another embodiment, the active heater may be a flexible film heater. The flexible film heater comprises a thin, flexible film containing embedded heating elements made from materials such as carbon, metal, or PTC materials. The flexible film heater may be affixed to or wrapped around individual battery cells or battery modules to provide uniform heat distribution. In some embodiments, the active heater may include a liquid-cooled heater. The liquid-cooled heater circulates a heated fluid around or through the battery pack to transfer heat. The fluid may be heated by external means, such as a resistive heating element, or by utilizing excess heat generated within the battery cells. In this embodiment, the liquid-cooled heater provides effective heat management, especially in high-capacity battery storage systems. In further embodiments, the active heater comprises an induction heater. The induction heater is configured to generate heat within conductive materials using an alternating magnetic field. This method provides precise control over localized heating within the battery pack. In yet another embodiment, the active heater may include a heat pump system. The heat pump system is configured to transfer heat from an external source to the battery pack using a refrigeration cycle. In some embodiments, the heat pump system may be capable of both heating and cooling the battery pack, depending on the environmental conditions. In some embodiments, the active heater may be combined with thermal pads utilizing phase change materials (PCMs). The thermal pads are configured to absorb and release heat as the phase change material transitions between solid and liquid phases. The active heater, in combination with the thermal pads, may provide thermal stability by storing and releasing excess heat. In yet another embodiment, the active heater may comprise a self-heating battery. The self-heating battery includes an integrated resistive heating element, which is activated based on detected temperature conditions. This internal heating element enables the battery to self-regulate its temperature in response to cold conditions without the need for external heating components. In further embodiments, the active heater may include an external air heater. The external air heater is configured to blow heated air over the battery pack. The air is heated using a resistive heating element or a heat pump system, thereby raising the temperature of the battery cells.

Each of these active heater embodiments may be selected based on the specific operating conditions of the battery storage system 100, including environmental temperature, battery size, power requirements, and safety considerations.

In some embodiments, a logic to activate the active heater circuit can include if minimum cell temperature is below 2° C., and if contactor is open and external voltage is above 12.5V, or if contactor is closed and current is above 5 Amps, then turn the heater ON, run the timer for 5 seconds. In addition, if minimum cell temperature is above 5° C., or if contactor is closed, and idle or discharge current, then turn the heater OFF. In addition, if the external voltage is below 11.5V, and the contactor is open, and timer is expired, then turn the heater OFF, run the timer for (5* tries counter) seconds.

In some embodiments, the BMS 10 includes a controller area network (CAN) bus interface, port or transceiver 48 as shown. The CAN bus enables data exchange between the master controller 40 and one or more external devices such as computing device having a BMS application, a dongle (e.g. providing state monitoring, user control, log transfer, etc.), and/or another power system device via RV-C protocol (e.g. alternators, inverters, etc.)

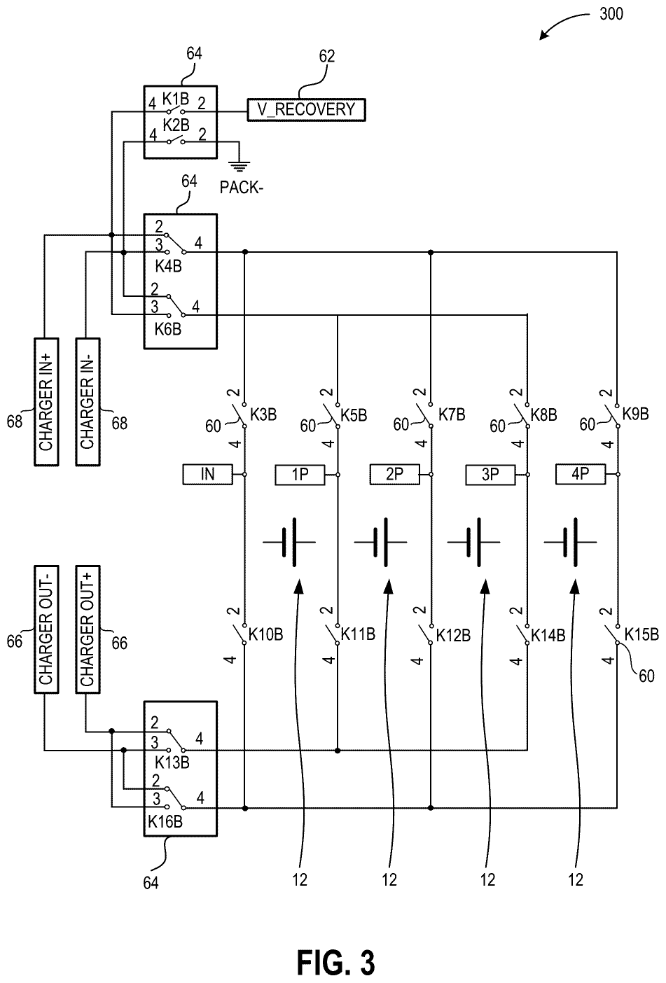

The active balancer 50 may control the balancing mode with a balancing circuitry 300 as shown by way of example in FIG. 3.

As shown in FIG. 3, the balancing circuitry 300 may include a plurality of relays 60, e.g. electromagnetic relays, for cell switching. In a variant, the relays 60 may be other types of switches or relays such as solid-state relays. The cell switching enables current to be drawn from the highest-voltage cell and directed to the lowest voltage cell. As further depicted in FIG. 3, a recovery circuit may be integrated. A recovery voltage source denoted V_{recovery} 62 is connected via additional relay pairs 64 as shown to enable a normal charging mode or a recovery mode. FIG. 3 also shows the battery terminals labeled Charger OUT denoted 66 and external power source terminals labeled Charger IN denoted 68.

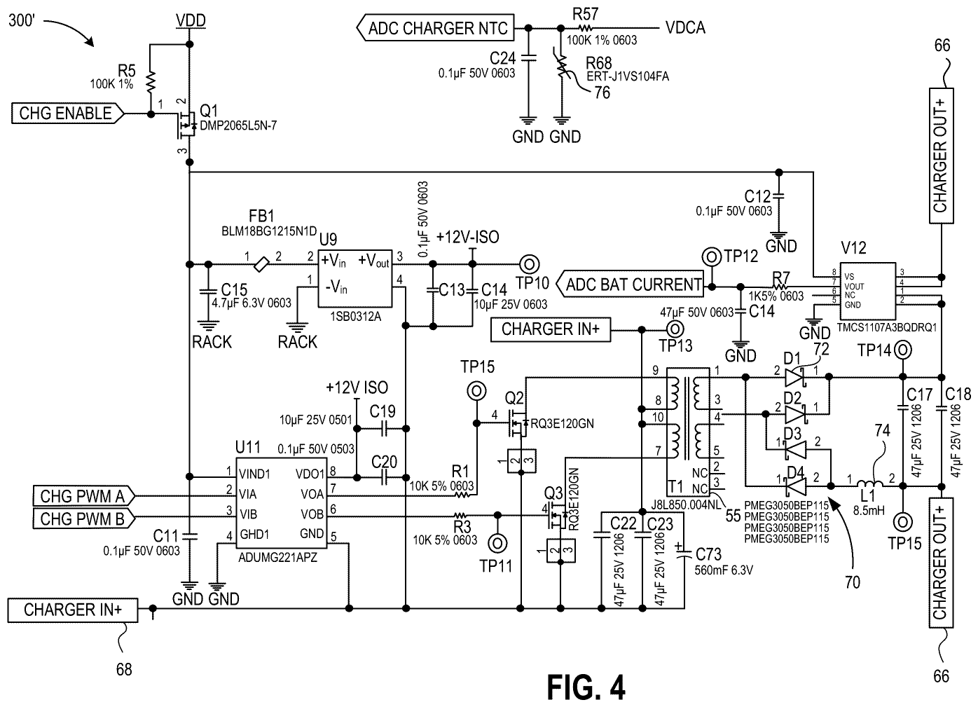

In the embodiment depicted in FIG. 4, the balancing circuitry 300′ includes a voltage converter 55 and an output rectifier circuit 70 having a plurality of Schottky diodes 72 individually labeled D1, D2, D3, D4 that may be configured in a Larionov circuit. Four such diodes are present in this rectifier circuit 70 but it will be appreciated that the numbers of such diodes may be varied to achieve a similar result.

In one embodiment, the voltage converter 55 includes a pulse transformer for galvanic isolation. The voltage converter 55 may be controlled by a microcontroller using an isolated power switch driver. The balancing current may be measured by an integral Hall-effect sensor in the output rectifier circuit. This balancing current may be used as feedback for a software PID controller in the microcontroller. During initial testing, overheating of the power switches was observed at a balancing current of 2 A or more with a low-resistance resistor with a resistance of 0.5 Ohm and a power of 20 W as load. A strong parametric resonance was observed at a natural frequency of about 200 kHz causing a current overload of the power switches. The inherent parametric resonance of the tested circuit was believed to be due to transient processes of the Schottky diodes of the output rectifier. The addition of an inductor to the output rectifier circuit had the effect of reducing the inherent parametric resonance of the Schottky diodes. Accordingly, in the embodiment illustrated in FIG. 4, the output rectifier circuit 70 includes an inductor 74 to minimize inherent parametric resonance of the Schottky diodes. Further testing revealed that long-term operation at balancing currents close to the maximum led to overheating of the diodes. To address this, in the illustrated embodiment of FIG. 4, the output rectifier circuit 50 includes a thermistor 76 (e.g. a thermistor R68). The thermistor is used to control a board temperature of an area of a board to which the Schottky diodes are mounted to prevent overheating of the Schottky diodes.

The active balancer 50 described here provides an improved cell-to-cell balancing mechanism that equalizes the voltage in the plurality cells 12. The active balancer 50 is energy-efficient because it transfers charge from the highest-voltage cell to the lowest-voltage cell instead of dumping excessive power to ground. Advantageously, cell excessive power is also not dissipated as waste heat.

The active balancer 50 can also provide battery pack-to-cell balancing mechanism that equalizes the voltage in the plurality cells 12 that is used when the BMS 10 enters into recovery mode, which is enabled when there is a cell that reaches a deep discharge state.

The battery storage system described herein may be used to control and balance a lithium-based rechargeable battery, such as a lithium-ion or lithium polymer battery. Excellent thermal management results have been achieved using a LiFePO₄ battery having a cell capacity of 72 Ah to 230 Ah. The battery storage system described herein may be used with a rechargeable battery configured as a 4s1p, 4s2p or 4s3p. A 4s1p battery is a type of battery pack that includes four cells connected in series (4s) and one cell in parallel (1p), whereas a 4s2p battery includes four cells in series and two in parallel, and whereas 4s3p battery includes four cells in series and three in parallel. The reader will readily understand that the battery storage system 100 or components thereof, such as the BMS 10 may be used, or adapted for use, with other types of batteries and/or other cell configurations.

The BMS 10 may be powered by the plurality of cells 12 or it may be powered by an external power source, thereby enabling stand-alone operation and basic operations in case the battery is unable to power the BMS.

### Battery Energy Storage System User Interface

In another broad aspect, the battery energy storage system 100 described herein is configured to establish a communication link with one or more computing device(s), such as one or more of a personal computer, a display device, or a mobile communication device (e.g., smart phone or tablet). For example, the display device can be a vehicle-mounted display unit.

In some embodiments, the battery storage system 100 described herein is configured to establish a communication link with a display device and/or a mobile communication device.

In some embodiments, establishing such communication link allows a user to perform one or more operations relating to the battery storage system 100. For example, receive information about the status of one or more battery packs contained in the battery storage system 100; distribute the load between a plurality of battery packs contained in the battery storage system 100 (e.g., by turning off/on certain battery packs); retrieving logs of each of the one or more battery packs contained in the battery storage system 100; provide user defined or manufacturer defined safe operating parameter range to the BMS 10; update associated firmware in a timely manner; ability to manage or command other devices including charge and or loads; and the like.

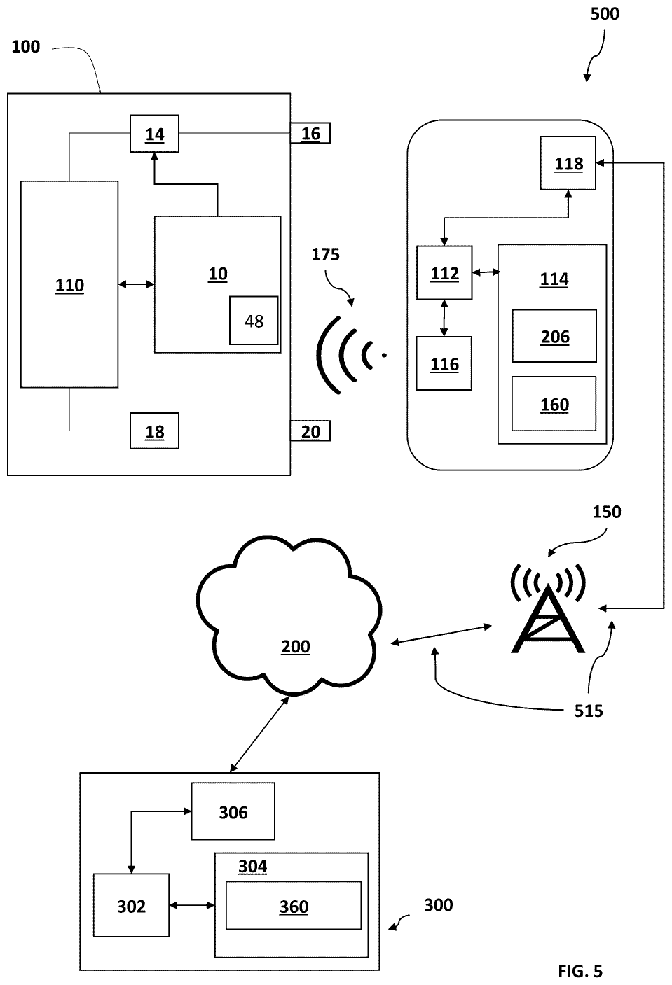

In some embodiments, as shown in FIG. 5, the battery storage system 100 can be configured to establish a communication link with computing device 500, which includes a processing unit 112, memory 114 in communication with the processing unit 112, a communication interface 116 for communicating with the BMS 10, and a network interface 118. The communication interface 116 may include any suitable wireless communication link for communicating with the BMS 10, depending on application specifics. Such wireless communication link allows exchanging information between the BMS 10 and the computing device 500, for example uploading/downloading data. Such data may relate for example to one or more of battery serial number, cell voltage and/or temperature of each cells, battery voltage and/or temperature, battery current optionally with direction (i.e., charging, discharging, idle), contactors position (closed/open), battery status, etc.

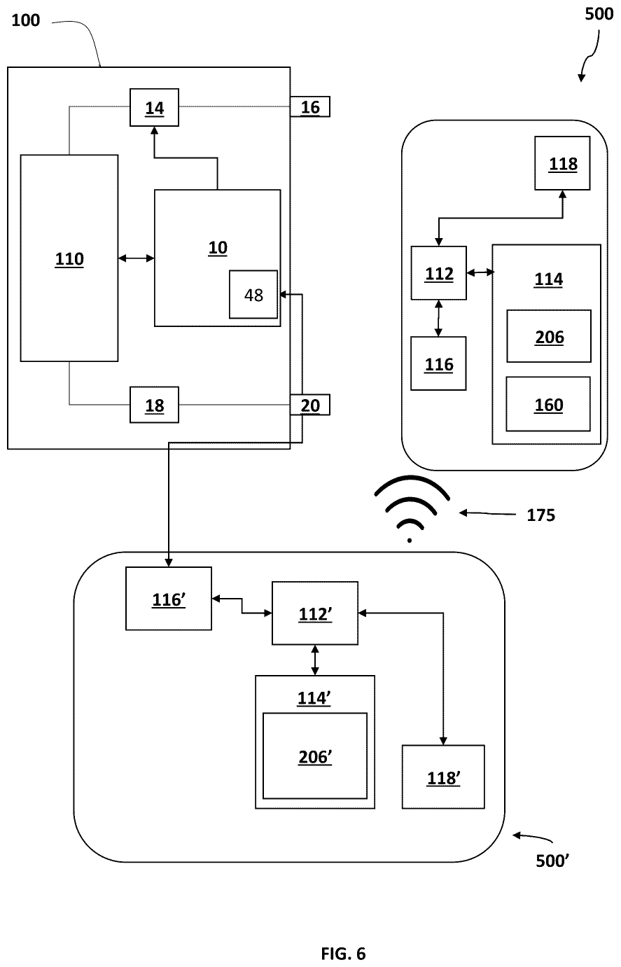

In some embodiments, as shown in FIG. 6, the battery storage system 100 can be configured to establish a communication link with computing device 500′, which includes a processing unit 112′, memory 114′ in communication with the processing unit 112′, a communication interface 116′ for communicating with the BMS 10, and a network interface 118′. The communication interface 116′ may include any suitable wired communication link for communicating with the BMS 10, depending on application specifics. Such wired communication link allows exchanging information between the BMS 10 and the computing device 500′, for example uploading/downloading data. Such data may relate for example to one or more of battery serial number, cell voltage and/or temperature of each cells, battery voltage and/or temperature, battery current optionally with direction (i.e., charging, discharging, idle), contactors position (closed/open), battery status, etc. In such embodiments, the computing device 500′ can communicate with the computing device 500 with its network interface 118′ through the communication interface 116 of the computing device 500.

In some embodiments, the herein described wireless or wired communication link for communicating with the BMS 10 allows a user to interact with the computing device 500 or 500′ to control and monitor the battery pack protection management and/or capacity management functionalities of the BMS 10. For example, the computer-readable instructions 206, 206′ in code when executed by the processor 112, 112′ of the computing device 500, 500′ may cause the computing device 500, 500′ to implement an energy management system (EMS).

For example, the EMS may include a data acquisition module which is connected to an external data processing module via a network, such as the Internet. The external data processing module can include an information collection terminal, a historical data change calculation unit, and a network connector. The information collection terminal receives data from the BMS 10, while the historical data change calculation unit compares and calculates the operational data of the battery energy storage system 100 over multiple time intervals to derive a health state value for the battery energy storage system 100, and if required, provide instructions to the BMS 10 to control or manage the first and/or second circuit operations.

For example, implementing the EMS may include displaying a user configuration screen to enable a user to set user defined safe operating parameter ranges, e.g., voltage limits and/or temperature limits. Such user defined safe operating parameter ranges can then be uploaded to the BMS 10.

Meanwhile, the computer-readable instructions 206, 206′ in code when executed by the processor 112, 112′ of the computing device 500, 500′ may cause the computing device 500, 500′ to transmit charging/discharging instruction to the BMS 10 to realize a charging or discharging operation. In the process of charging/discharging, the BMS 10 collects data of the one or more battery packs. The collected data can include a total charging/discharging current (of each of the one or more battery packs), a total voltage of the one or more battery pack, a current flowing through each of the one or more battery pack, and a charging/discharging voltage of a cell (that is, a cell in a respective one of the one or more battery pack). In addition, through comparison of the currently acquired voltage and current with the key charging/discharging control parameter stored in the memory, the charging/discharging control parameter includes the total maximum transient and continuous charging/discharging current through each of the one or more battery pack, a total charging/discharging voltage threshold of the cell, and the like. If any of the present total charging/discharging currents through each of the one or more battery pack or the voltage of a given cell exceeds the threshold of the key control parameter of the BMS 10, the master controller 40 gives an alarm and cuts off the current for safety protection of the respective one of the one or more battery packs. The master controller 40 determines, according to the maximum power or/and total energy demands for charging or discharging of the one or more battery pack by the EMS and the present SOC of each cell of the one or more battery pack, the present charging or discharging current and a time interval and a threshold for charging or discharging of each of the one or more battery pack under the control of the BMS 10, and the master controller 40 is configured to perform active balancing as discussed previously.

In FIG. 5 the communication interface 116 communicates with the CAN bus transceiver 48 over communication link 175. In FIG. 6, the communication interface 116 communicates with the network interface 118′ of the computing device 500′. In each case, the communication interface 116 may include a Bluetooth® transceiver, or any other suitable short-range communication protocol, e.g. Wi-Fi, ZigBee, NFC.

In some embodiments, the computing device 500 may also communicate over a data network 200 with remote server 300. The data network 200 can be a public data network (such as the Internet) or a local area network (a LAN). For example, the computing device 500 can be a mobile communication device that communicates with its network interface 118 over cellular link 515 with remote server 300, and the communication may be made via a cellular base station 150 and data network 200. The remote server 300 has a processing unit 302, a memory 304 in communication with the processing unit 302, and a communication port 306 (e.g. network interface, modem, router, etc.).

In some embodiments, the computing device 500, 500′ is programmed with suitable software instructions 206, 206′ in code for communicating and interacting with the BMS 10, and for implementing the EMS and/or user interface display.

In some embodiments, the computing device 500, 500′ may be programmed with suitable software instructions 206, 206′ for allowing the computing device 500, 500′ to obtain and store in its memory 114, 114′ an error log (not shown) in association with the BMS 10.

In some embodiments, the computing device 500 memory 114 stores suitable software instructions 206 which when executed by the processor 112 of the computing device 500 cause the computing device 500 to obtain and store in its memory 114 firmware update information 160 in association with the BMS 10 and/or with the computing device 500′. The computing device 500 may obtain the firmware update information 160 in any number of suitable ways including, without being limited to:
a. accessing the remote server 300 via cellular link 515 via cellular base station 150 and data network 200, wherein the remote server 300 may store the firmware update information in its own memory 304;
b. receiving a communication (such as an e-mail message over a network from another device conveying the firmware update information;
c. establishing a communication link over a communication interface with a memory device, such as a USB stick, wherein the memory device stores the firmware update information.

In some embodiments, the computing device 500, 500′ can communicate with the BMS 10 to obtain battery status data or to obtain various operating parameters from the BMS 10, such as voltage limits or temperatures limits. The computing device 500, 500′ may communicate directly or indirectly with the remote server 300 to transmit battery status data and to receive diagnostics data generated based on the battery status data.

In some embodiments, the remote server 300 may also communicate with the computing device 500 to transmit an over-the-air update or patch. The mobile communication device 500 can then transmit the update or patch to the BMS 10 and/or to the computing device 500′.

In some embodiments, the remote server 300 may send a notification to the computing device 500 that an update or patch is available. The user of the computing device 500 can then download the update or patch over cellular link 515 and then transfer the update or patch to the BMS 10 and/or to the computing device 500′ over communication link 175. In other embodiments, the update or patch may be automatically transferred to the BMS 10, without sending a notification to the computing device 500.

In some embodiments, the computing device 500, 500′ includes a non-transitory computer-readable medium 114, 114′ storing computer-readable instructions 206, 206′ in code, which when executed by processor 112, 112′ of the computing device 500, 500′ causes the computing device 500, 500′ to perform one or more of the following computer-implemented method steps.

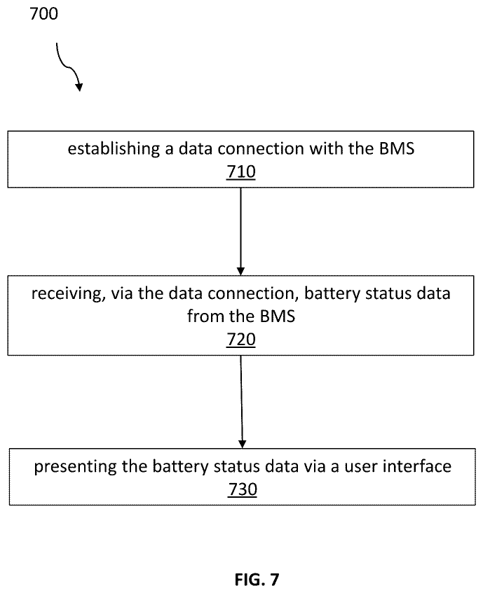

FIG. 7 illustrates a practical implementation of a computer-implemented process 700. At step 710, the computer-readable instructions 206, 206′ in code when executed by the processor 112, 112′ of the computing device 500, 500′ cause the computing device 500, 500′ to establish communication link 175 with the BMS 10. At step 720, the computing device 500, 500′ receives, via the communication link 175, battery status data from the BMS 10. At step 730, the computing device 500, 500′ presents the battery status data to a user via a user interface. In one embodiment, the battery status data can comprise data logs of voltage and/or state of charge (SoC) as a function of time.

Optionally, the computer-readable instructions 206, 206′ in code when executed by the processor 112, 112′ of the computing device 500, 500′ may cause the computing device 500, 500′ to receive voltage limits and temperature limits for the plurality of cells 12 of the battery pack 110 that are stored in a memory of the BMS 10.

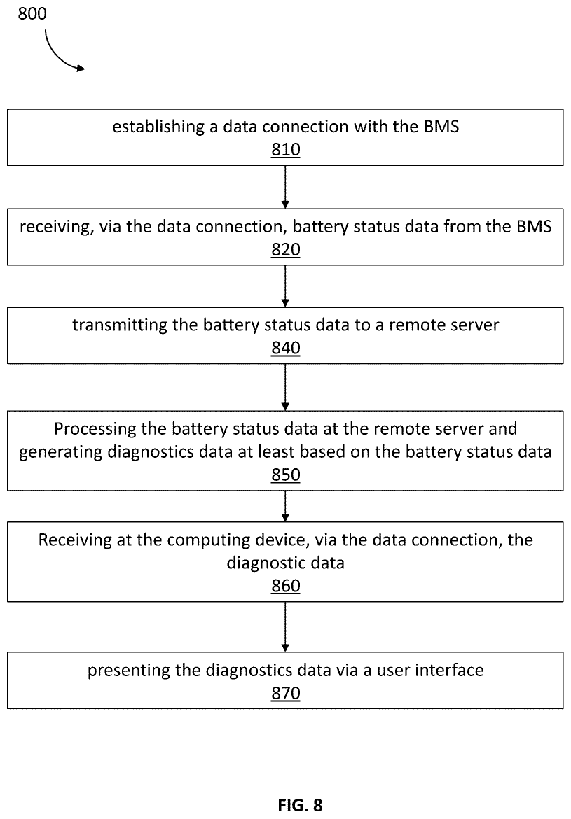

FIG. 8 illustrates another practical implementation of a computer-implemented process 800. At step 810, the computer-readable instructions 206, 206′ in code when executed by the processor 112, 112′ of the computing device 500, 500′ may cause the computing device 500, 500′ to establish communication link 175 with the BMS 10. At step 820, the computing device 500, 500′ receives, via the communication link 175, battery status data from the BMS 10. At step 840, the computing device 500 transmits the battery status data to remote server 300 over a communication link (e.g., cellular link 515). The server 300 can then process the battery status data using its processor 302 and instructions 360 stored in its memory 304 to generate diagnostics data at least based on the battery status data, step 850. At step 860, the computing device 500 receives (e.g., downloads) the diagnostic data from the server 300 over the communication link (e.g., cellular link 515). At step 870, the computing device 500 either directly presents the diagnostic data to a user via a user interface and/or transmits the diagnostic data to the computing device 500′ over communication link 175 and the computing device 500′ presents the diagnostic data to a user via a user interface.

In some embodiments, the user interface may be an audio interface, a graphical user interface (GUI), and the like.

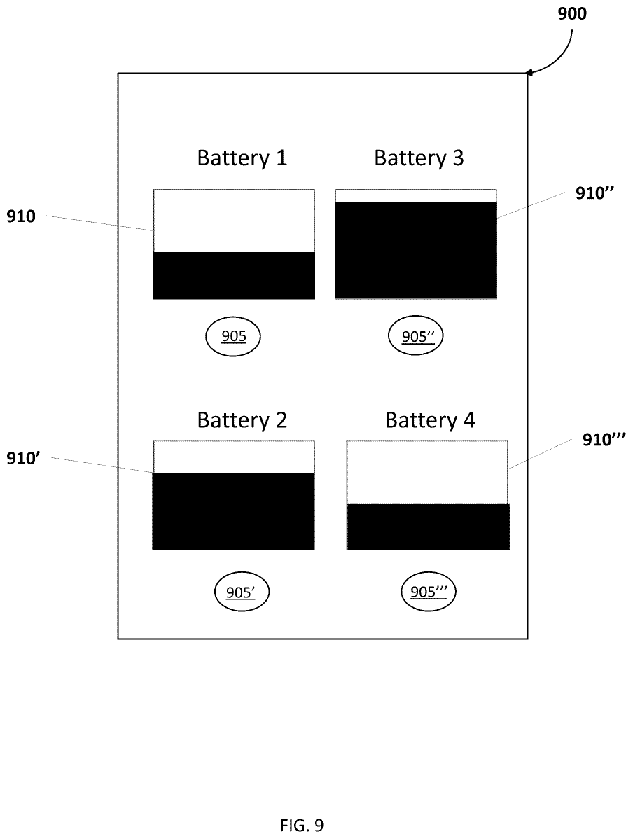

In some embodiments, the data may be presented to a user via a user interface, for example a graphical user interface (GUI). For example, FIG. 9 shows a non-limiting GUI 900 which is presented via either or both the computing device 500, 500′ and/or display associated therewith. The data can be displayed as colored graphs 910 corresponding to each battery pack connected to the computing device 500 or 500′. In the embodiment shown in FIG. 9, there are four batteries connected to the computing device 500 or 500′, and the GUI 900 presented via a display associated with the computing device 500 or 500′ illustrates the data as graphs 910, 910′, 910″, 910″' each corresponding to one of the four batteries and providing information associated with the respective battery pack, such as energy available (remaining energy being indicated in FIG. 9 with the solid black rectangle). The user can interact through the GUI 900 to collapse and expand the graphs. When the computing device 500 or 500′ is a smartphone, the graphs can be scaled with smartphone gestures. The GUI 900 can include interaction items 905, 905′, 905″, 905″' to expand additional interaction items specific to each battery or to turn OFF/ON the respective battery, for example.

In some embodiments, the battery energy storage system 100 described herein includes a plurality of rechargeable battery packs 110 . . . 110n, where each battery pack 110 can establish a communication link with one another to communicate the respective battery status. In such cases, the BMS 10 can analyze the battery status of each other and determine how to manage each battery pack 110 in the plurality of rechargeable battery packs 110 . . . 110n. For example, disconnect a given battery pack 110, allow a given battery pack 110 to recharge, close a given contactor 14, etc. For example, each battery pack 110 can be directly connected to one another, in parallel, such as via CAN bus wires, and the like. As such, the plurality of rechargeable battery packs 110 . . . 110n can share data through bus communication.

In such embodiments, each battery pack 110 is capable of independently charging based on its condition. This approach avoids overcharging or undercharging that can occur due to uniform charging, thereby prolonging the service life of the plurality of rechargeable battery packs 110 . . . 110n. During discharge, the plurality of rechargeable battery packs 110 . . . 110n cooperate in an adaptive manner to meet the load power requirements, optimizing the use of electrical energy resources and improving energy utilization efficiency. This method also prevents over-discharge of certain battery packs during unified discharging, further extending the battery packs' service life. Further, in both charging and discharging modes, an individual battery pack 110 may cease operation in the event of a fault or insufficient electric quantity (preventing further discharging). The remaining operational battery packs 110 can continue charging or discharging as normal, thus enhancing reliability and ensuring high system stability.

Other examples of implementations will become apparent to the reader in view of the teachings of the present description and as such, will not be further described here.

Although the term “processing unit” or “CPU” is used throughout this document, it is appreciated that any suitable processor for executing logic and/or program code setting out the various functions, procedures and/or methods described in this document may be used. Such examples include a microprocessor, digital signal processors (DSP), application-specific integrated circuit (ASIC), field-programmable gate array (FPGA), etc.

Note that titles or subtitles may be used throughout the present disclosure for convenience of a reader, but in no way these should limit the scope of the disclosure. Moreover, certain theories may be proposed and disclosed herein; however, in no way they, whether they are right or wrong, should limit the scope of the disclosure so long as the disclosure is practiced according to the present disclosure without regard for any particular theory or scheme of action.

All references cited throughout the specification are hereby incorporated by reference in their entirety for all purposes.

Reference throughout the specification to “some embodiments”, and so forth, means that a particular element (e.g., feature, structure, and/or characteristic) described in connection with the disclosure is included in at least one embodiment described herein, and may or may not be present in other embodiments. In addition, it is to be understood that the described inventive features may be combined in any suitable manner in the various embodiments.

It will be understood by those of skill in the art that throughout the present specification, the term “a” used before a term encompasses embodiments containing one or more to what the term refers. It will also be understood by those of skill in the art that throughout the present specification, the term “comprising”, which is synonymous with “including,” “containing,” or “characterized by,” is inclusive or open-ended and does not exclude additional, un-recited elements or method steps.

Unless otherwise defined, all technical and scientific terms used herein have the same meaning as commonly understood by one of ordinary skill in the art to which this disclosure pertains. In the case of conflict, the present document, including definitions will control.

As used in the present disclosure, the terms “around”, “about” or “approximately” shall generally mean within the error margin generally accepted in the art. Hence, numerical quantities given herein generally include such error margin such that the terms “around”, “about” or “approximately” can be inferred if not expressly stated.

Although various embodiments of the disclosure have been described and illustrated, it will be apparent to those skilled in the art considering the present description that numerous modifications and variations can be made. The scope of the disclosure is defined more particularly in the appended claims.

1. A battery energy storage system, comprising:
a) one or more rechargeable battery packs, each including a plurality of battery cells; and
b) a battery management system (BMS) including a first circuitry configured for battery pack protection management and a second circuitry configured for capacity management, wherein the second circuitry is further configured to perform an auxiliary service while performing the capacity management,
wherein the first circuitry monitors an operating parameter of at least one cell of the plurality of cells to detect an occurrence of the operating parameter being outside a predetermined safe operating range and in response to detection of the operating parameter being outside the predetermined safe operating range, interrupts the battery pack,
wherein the second circuitry monitors cell voltage balancing of a plurality of cells of a relevant battery pack to detect an occurrence of a cell being in a state of unbalance, and in response to detection of the cell being in the state of unbalance, controls a cell-to-cell active balancing of the plurality of cells by transferring current from a highest-voltage cell to a lowest voltage cell,
wherein the auxiliary service includes monitoring proper operation of the first circuitry and in response to detection of a faulty operation of the first circuitry, the second circuitry is configured to control the battery pack protection management.

2. The battery energy storage system according to claim 1, wherein the second circuitry establishes a communication link with an external system, wherein the external system includes a computing device.

3. The battery energy storage system according to claim 2, wherein the computing device communicates with the BMS to perform one or more of: obtain and process diagnostic data, control or manage the protection management and capacity management functionalities, and control or manage charging or discharging activity of the one or more rechargeable battery packs.

4. The battery energy storage system according to claim 1, wherein the auxiliary service further includes one or more of: communicating one or more operating parameter limits to the first circuitry, monitoring measurement results of the first circuitry, managing a failure mode in case the battery pack protection management fails, save battery storage system status to a computer readable storage device, manage system power modes, control a recovery circuit to charge a deeply discharged cell that has been discharged below a lower voltage limit, and control an active heater for heating the battery pack.

5. The battery energy storage system according to claim 1, wherein the battery pack and the BMS are connected to each other when there is an external device connected to the battery storage system.

6. The battery energy storage system according to claim 1, wherein the operating parameter includes one or more of cell voltage, battery pack voltage, cell temperature, battery pack current, or a state of balance of the plurality of cells.

7. The battery energy storage system according to claim 1, wherein the first circuitry monitors at least a voltage of a cell of the plurality of cells, and in response to detection of the voltage of the cell exceeding a voltage limit, the first circuitry is configured to interrupt the battery pack to prevent damage to the battery pack.

8. The battery energy storage system according to claim 7, further comprising a contactor electrically connecting the battery pack to a positive or negative terminal of the battery storage system, wherein the first circuitry interrupts the battery pack by controlling the contactor to disconnect the battery pack from the respective positive or negative terminal.

9. The battery energy storage system according to claim 7, further comprising a voltage sensor, probe or transducer connected to the plurality of cells, wherein the voltage sensor, probe or transducer is configured for measuring the voltage of the cell of the plurality of cells and transmitting the cell voltage measurement to the first circuitry.

10. The battery energy storage system according to claim 1, wherein the second circuitry is in communication with the first circuitry via a communication interface, and is configured for communicating the safe operating parameter range to the first circuitry.

11. The battery energy storage system according to claim 1, wherein in response to detection of a state of balance of the plurality of cells indicative that a cell is in a state of unbalance, the second circuitry is configured to control an active balancer for performing the cell-to-cell active balancing of the plurality of cells.

12. The battery energy storage system according to claim 1, wherein the system includes a plurality of rechargeable battery packs, and wherein each battery pack can establish a communication link with one another to communicate the respective battery status.

13. The battery energy storage system according to claim 1, wherein the capacity management is performed when the battery storage system is in charging, discharging, idle and sleep mode.

14. The battery energy storage system according to claim 1, wherein the system is associated with an electric vehicle.

15. A method for managing a battery energy storage system, the battery energy storage system including
a) one or more rechargeable battery packs, each including a plurality of battery cells; and
b) a battery management system (BMS) including a first circuitry configured for battery pack protection management and a second circuitry configured for capacity management, wherein the second circuitry is further configured to perform an auxiliary service while performing the capacity management,
the method comprising:
i) with the first circuitry, monitoring an operating parameter of at least one cell of the plurality of cells to detect an occurrence of the operating parameter being outside a predetermined safe operating range, and in response to detection of the operating parameter being outside the predetermined safe operating range, interrupting the battery pack;
ii) with the second circuitry, monitoring cell voltage balancing of a plurality of cells of a battery pack to detect an occurrence of a cell being in a state of unbalance, and in response to detection of the cell being in the state of unbalance, controlling a cell-to-cell active balancing of the plurality of cells by transferring current from a highest-voltage cell to a lowest voltage cell; and
iii) with the second circuitry, monitoring proper operation of the first circuitry and in response to detection of a faulty operation of the first circuitry, control the battery pack protection management

16. The method of claim 15, further comprising with the second circuitry establishing a communication link with an external system, wherein the external system includes a computing device.

17. The method of claim 16, wherein the computing device communicates with the BMS to perform one or more of: obtain and process diagnostic data, control or manage the protection management and capacity management functionalities, and control or manage charging or discharging activity of the one or more rechargeable battery packs.

18. The method of claim 15, wherein the operating parameter includes one or more of cell voltage, battery pack voltage, cell temperature, battery pack current, or a state of balance of the plurality of cells.

19. The method of claim 15, further comprising with the first circuitry, monitoring at least a voltage of a cell of the plurality of cells, and in response to detection of the voltage of the cell exceeding a voltage limit, interrupt the battery pack to prevent damage to the battery pack.

20. The method of claim 19, wherein the battery storage system further comprises a contactor electrically connecting the battery pack to a positive or negative terminal of the battery storage system, wherein the first circuitry interrupts the battery pack by controlling the contactor to disconnect the battery pack from the respective positive or negative terminal.
